(19) United States
(12) Patent Application Publication
(10) Pub. No.: US 2017/0063700 A1
(43) Pub. Date: Mar. 2, 2017

(54) SYSTEMS AND METHODS FOR RATE DETECTION FOR SOUNDWIRE EXTENSION (SOUNDWIRE-XL) CABLES

(71) Applicant: QUALCOMM Incorporated, San Diego, CA (US)

(72) Inventors: Jin-Sheng Wang, Cupertino, CA (US); Lior Amarilio, Yokneam (IL)

(21) Appl. No.: 15/226,330

(22) Filed: Aug. 2, 2016

Related U.S. Application Data
(60) Provisional application No. 62/210,062, filed on Aug. 26, 2015.

(51) Int. Cl. H04L 12/825; G01R 19/25; G06F 13/42; H04L 7/033

(52) U.S. Cl. CPC H04L 47/25; H04L 7/033; G01R 19/2506; G06F 13/4282

(57) ABSTRACT

Systems and methods for rate detection for SOUNDWIRE extension (SOUNDWIRE-XL) cables are disclosed. In one aspect, software may be used to initiate a capability exchange between a host device and a slave device over a SOUNDWIRE-XL cable. In a second exemplary aspect, resistors may be associated with data lines in the slave device. Designers may encode rate information into the slave device by using different values for the elements. The host device may then sample the data lanes and determine a rate for the slave device.

### PRIORITY CLAIM

The present application claims priority to U.S. Patent Application Ser. No. 62/210,062 filed on Aug. 26, 2015 and entitled “RATE DETECTION FOR SOUNDWIRE CABLES,” the contents of which is incorporated herein by reference in its entirety.

### BACKGROUND

I. Field of the Disclosure

The technology of the disclosure relates generally to audio buses based on the SOUNDWIRE specification and particularly to the SOUNDWIRE extension (SOUNDWIRE-XL) specification.

II. Background

Mobile terminals have evolved from simple telephonic devices and cumbersome “laptop” computers to hybridized sophisticated multimedia platforms that allow users to perform relatively sophisticated computing functions as well as consume multimedia content. Vestigial telephonic functions are still available on some devices.

To help support the various multimedia capabilities, and to support the vestigial telephonic audio functions, many mobile computing devices include plural microphones and plural speakers coupled to an audio bus. One such audio bus that was adopted as an industry standard is the Serial Low-power Inter-chip Media Bus (SLIMbus) developed by the MIPI Alliance. However, the complexity of the SLIMbus standard resulted in relatively low industry deployment. Accordingly, the MIPI Alliance has announced the SOUNDWIRE specification. In some cases SOUNDWIRE may replace SLIMbus or it may be used concurrently.

Initially, the SOUNDWIRE specification was designed for audio elements positioned internal to the computing device, and thus, the distances involved for the bus were relatively short (i.e., less than fifty centimeters (50 cm)). Likewise, data rates for the devices were generally known a priori, and the system designer could clock the bus appropriately. However, commercial realities require the mobile computing device to interoperate with external devices that may be more than 50 cm away. Further, such external devices may be coupled and decoupled from the bus dynamically. Since each of the external devices may have different rate requirements there is a need to be able to communicate rate information from the external device to the host computing device.

### SUMMARY OF THE DISCLOSURE

Aspects disclosed in the detailed description include systems and methods for rate detection for SOUNDWIRE extension (SOUNDWIRE-XL) cables. In an exemplary aspect, software may be used to initiate a capability exchange between a host device and a slave device over a SOUNDWIRE-XL cable. In a second exemplary aspect, resistors or other elements may be associated with data lines in the slave device. Designers may encode rate information into the slave device by using different values for the elements. The host device may then sample the data lanes and determine a rate for the slave device.

In this regard in one aspect, a master device is disclosed. The master device includes a receptacle. The receptacle is configured to receive a SOUNDWIRE-XL cable. The master device also includes an interface. The interface includes a differential data line with an embedded clock signal. The interface is coupled to the receptacle. The master device also includes a control system. The control system is configured to generate voltage levels on the differential data line. The control system is also configured to detect the voltage levels on the differential data line as modified by a remote slave device. The control system is also configured to determine a data rate for the remote slave device based on the detected voltage levels.

In another aspect, a method of controlling a SOUNDWIRE-XL cable is disclosed. The method includes, at a master device, generating voltage levels on a differential data line. The method also includes detecting the voltage levels on the differential data line as modified by a remote slave device. The method also includes determining a data rate for the remote slave device based on the detected voltage levels.

In another aspect, a slave device is disclosed. The slave device includes a receptacle. The receptacle is configured to receive a SOUNDWIRE-XL cable. The slave device also includes an interface. The interface includes a differential data line having an embedded clock signal thereon. The interface includes at least on slave element configured to provide encoded data rate information about the slave device.

In another aspect, a method of detecting rate information for a remote slave device is disclosed. The method includes detecting voltage levels on a differential data line based on one or more pull-up resistors at a remote slave device. The method also includes decoding the voltage levels to determine a data rate.

### BRIEF DESCRIPTION OF THE FIGURES

FIG. 1A is a block diagram of an exemplary conventional simple SOUNDWIRE system;

FIG. 1B is a block diagram of an exemplary expanded SOUNDWIRE system with a bridge and SOUNDWIRE extension (SOUNDWIRE-XL) segment;

FIG. 1C is a block diagram of an exemplary expanded SOUNDWIRE system with multiple bridges and multiple SOUNDWIRE-XL segments;

FIG. 1D is a block diagram of another exemplary expanded SOUNDWIRE system with a bridge and multiple SOUNDWIRE-XL segments;

FIG. 2 is a flowchart of an exemplary software solution to determining rate information for remote devices in a SOUNDWIRE system having at least one SOUNDWIRE-XL segment;

FIG. 3 is a simplified circuit diagram of a hardware solution to determining rate information for remote devices in a SOUNDWIRE system having a SOUNDWIRE-XL segment;

FIG. 4 is a simplified circuit diagram of the hardware solution of FIG. 3 when the remote devices are unplugged;

FIG. 5 is a flowchart of a process associated with rate determination according to the hardware solution of FIG. 3;

FIG. 6 is a simplified circuit diagram of a hardware solution for determining rate information for remote devices using a hub; and

FIG. 7 is a block diagram of an exemplary processor-based system that can include the SOUNDWIRE systems of FIGS. 1B-1D, 3, 4, and 6.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include systems and methods for rate detection for SOUNDWIRE extension (SOUNDWIRE-XL) cables. In an exemplary aspect, software may be used to initiate a capability exchange between a host device and a slave device over a SOUNDWIRE-XL cable. In a second exemplary aspect, resistors or other elements may be associated with data lines in the slave device. Designers may encode rate information into the slave device by using different values for the elements. The host device may then sample the data lanes and determine a rate for the slave device.

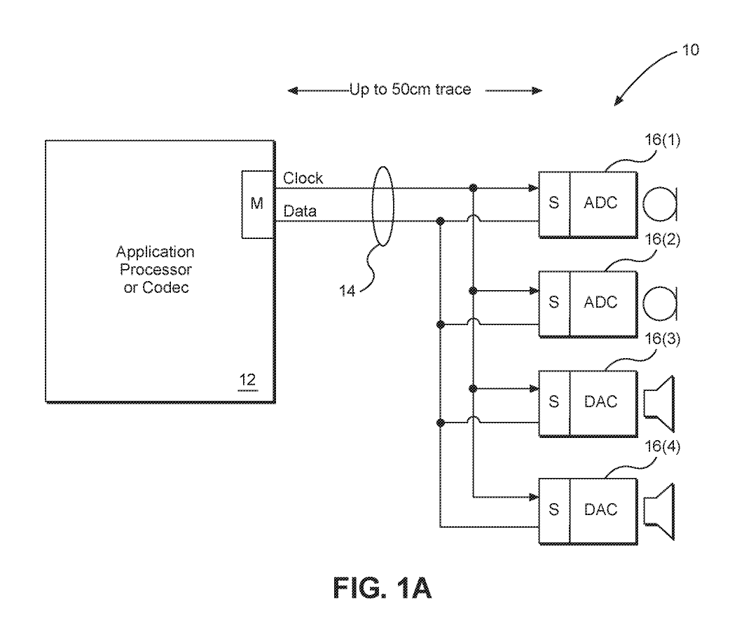

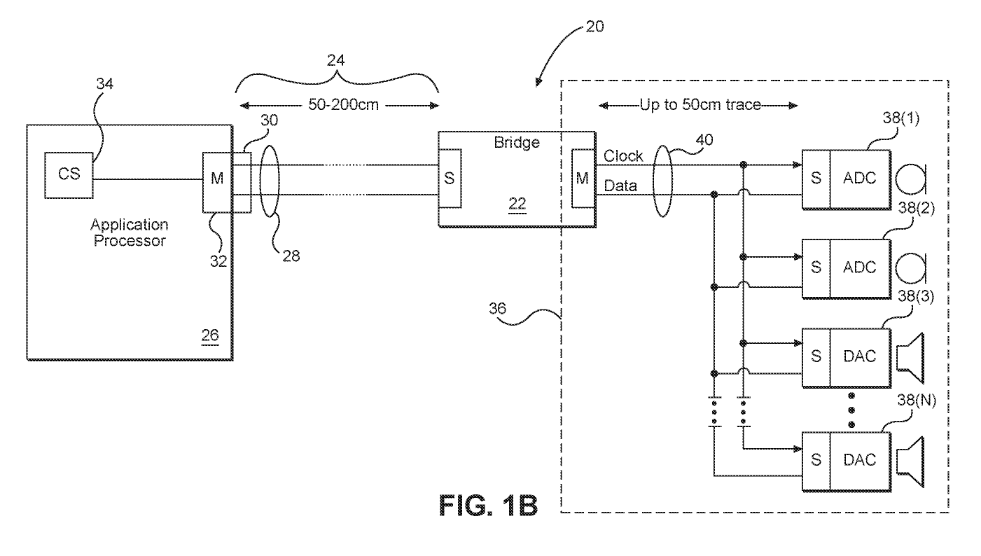

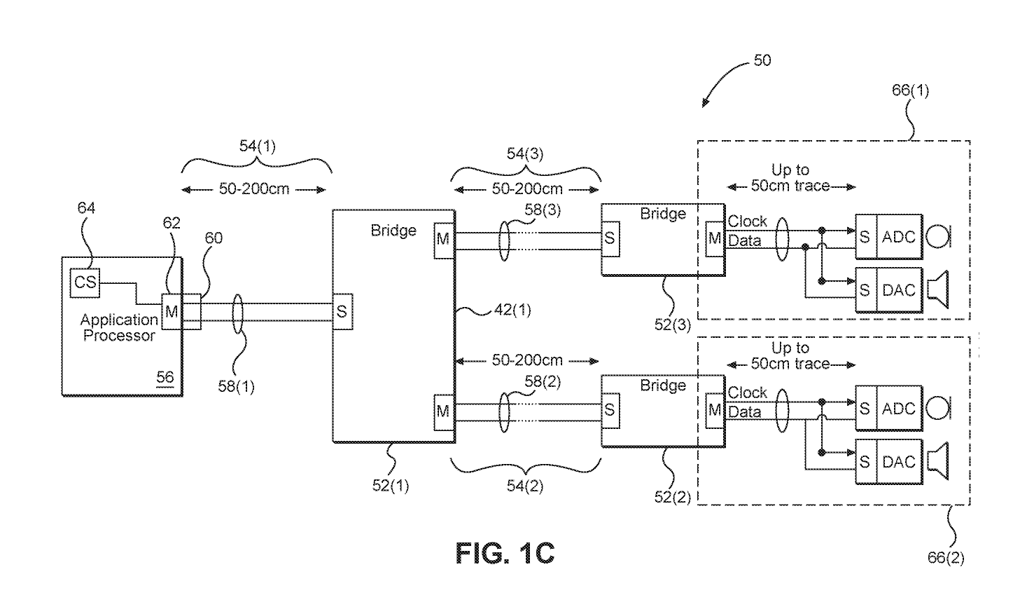

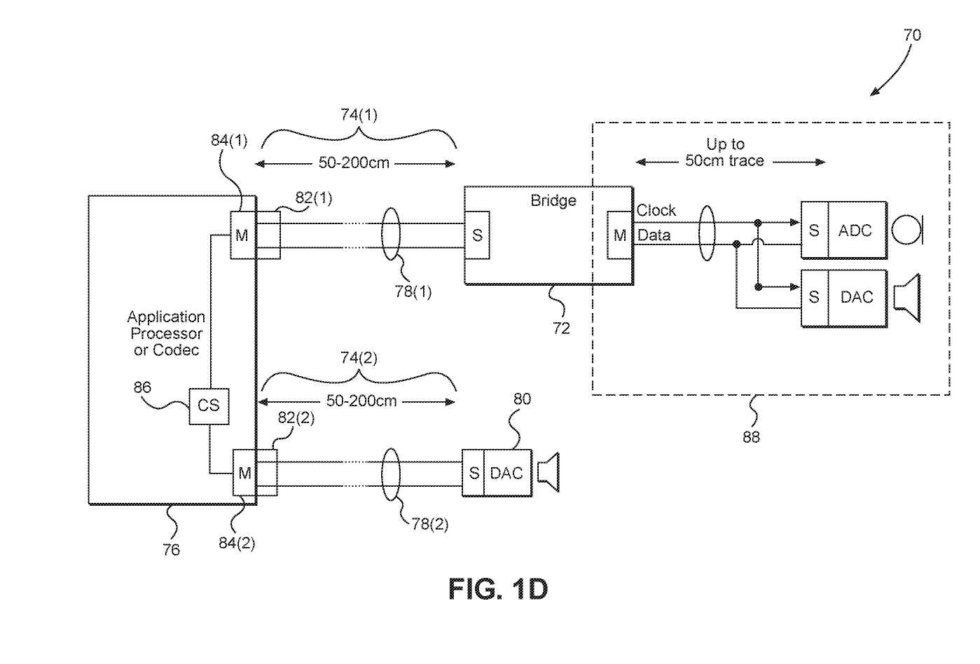

Before addressing particular aspects of the present disclosure, an exemplary SOUNDWIRE system is presented in FIG. 1A, followed by alternate SOUNDWIRE systems having one or more SOUNDWIRE-XL segments and/or one or more SOUNDWIRE bridges that may benefit from using exemplary aspects of the present disclosure. In particular, by allowing a master to determine what data rate is used by a remote slave, the master may modify or reconfigure a data line to use the appropriate data rate. Such flexibility on the part of the master allows for greater interoperability between devices from different manufacturers as well as more readily accommodates removable devices such as a headset.

In this regard, FIG. 1A is a simplified block diagram of an exemplary conventional simple SOUNDWIRE system 10. The SOUNDWIRE system 10 may include a host or master device, which may be an application processor 12 or other form of codec. The application processor 12 is coupled to a SOUNDWIRE bus 14. The application processor 12 communicates with slave devices 16(1)-16(4) through the SOUNDWIRE bus 14. As is understood, the SOUNDWIRE bus 14 contains a clock line and a data line. The SOUNDWIRE specification allows the data line to be up to eight data lines, but only one is referenced herein for simplicity. The slave devices 16(1)-16(4) may be audio devices such as a microphone or speaker and include appropriate digital to analog circuitry (DAC) or analog to digital circuitry (ADC) as is well understood. In conventional SOUNDWIRE systems such as the SOUNDWIRE system 10, the SOUNDWIRE bus 14 is no more than fifty centimeters (50 cm) in length. Likewise, in conventional SOUNDWIRE systems such as the SOUNDWIRE system 10, the designer knows a priori what rate each of the slave devices 16(1)-16(4) requires and can set the rate for the SOUNDWIRE bus 14 accordingly. While having a predetermined configuration of the slave devices 16(1)-16(4) simplifies design parameters, such fixed system ignores the realities of how people use computing devices. In particular, people may want to use earbuds, other forms of remote speakers, headsets, or other remote audio elements. Such remote elements may dynamically be associated with the SOUNDWIRE bus 14 (e.g., such as insertion of an audio jack into an audio receptacle on the computing device) and may include cords that are in excess of 50 cm.

Recent proposals within the SOUNDWIRE community contemplate the addition of a SOUNDWIRE extension that may be as long as two hundred centimeters (200 cm) and allow for dynamic association with a SOUNDWIRE bus. Preliminary discussions with MIPI sometimes refer to the SOUNDWIRE extension as “SOUNDWIRE-XL.” However, while SOUNDWIRE-XL provides end users desired flexibility, SOUNDWIRE-XL creates the possibility that a new device may have a data rate different than other components associated with the master device through the SOUNDWIRE bus and the master device must adjust the data rate on the SOUNDWIRE-XL bus. However, the problem remains as to how the master device learns of the data rate for the new device. Exemplary aspects of the present disclosure provide different techniques for rate detection on SOUNDWIRE-XL cables. Before addressing these techniques for rate detection, a few exemplary SOUNDWIRE systems that include SOUNDWIRE-XL cables and bridges that will benefit from these techniques are provided with reference to FIGS. 1B-1D.

In this regard, FIG. 1B is a block diagram of an exemplary expanded SOUNDWIRE system 20 with a bridge 22 and a SOUNDWIRE-XL segment 24 formed between an application processor 26 and the bridge 22 by a SOUNDWIRE-XL cable 28. The SOUNDWIRE-XL cable 28 is a two-wire cable configured to carry a differential signal thereover. The application processor 26 is a master device relative to the bridge 22. While described as an application processor 26, it should be appreciated that the master device may instead be a codec or other element as is well understood. The application processor 26 may be in a device such as a mobile computing device (not shown) that includes a receptacle 30 configured to receive a SOUNDWIRE-XL cable such as the SOUNDWIRE-XL cable 28. The SOUNDWIRE-XL cable 28 may be up to two meters (2 m or 200 cm) long. The receptacle 30 may be operatively associated with an interface 32 (which may or may not be in the application processor 26) that includes appropriate electrical contacts to convey a differential data signal with an embedded clock signal to the two wires of the SOUNDWIRE-XL cable 28. The interface 32 may further be operatively coupled to a control system (labeled CS in the Figures) 34. The function of the control system 34 is explored in greater detail below.

With continued reference to FIG. 1B, the bridge 22 is configured to operate as a slave device relative to the application processor 26, and translate SOUNDWIRE-XL signals to SOUNDWIRE signals for use on a SOUNDWIRE system 36. In the SOUNDWIRE system 36, the bridge 22 acts as a master device and is configured to send and receive signals to slave devices 38(1)-38(N) through a SOUNDWIRE bus 40.

It is anticipated that the SOUNDWIRE-XL cable 28 will be selectively removable from the receptacle 30. Because the bridge 22 may be selectively attached to the application processor 26 by an end user, the application processor 26 may not know what rate is appropriate to use over the SOUNDWIRE-XL cable 28. Exemplary situations of the expanded SOUNDWIRE system 20 include a headset with noise cancelation features, a docking station connection for an audio system, and a mobile terminal coupled to a large display.

Similarly, FIG. 1C is a block diagram of an exemplary expanded SOUNDWIRE system 50 with multiple bridges 52(1)-52(3) and multiple SOUNDWIRE-XL segments 54(1)-54(3). SOUNDWIRE-XL segment 54(1) is formed between an application processor 56 and bridge 52(1) by a SOUNDWIRE-XL cable 58(1). Similarly, SOUNDWIRE-XL segments 54(2) and 54(3) are formed between the bridge 52(1) and bridges 52(2) and 52(3) by SOUNDWIRE-XL cables 58(2) and 58(3), respectively. The SOUNDWIRE-XL cables 58(1)-58(3) are two-wire cables configured to carry differential signals thereover. The application processor 56 is a master device relative to the bridge 52(1). While described as an application processor 56, it should be appreciated that the master device may instead be a codec or other element as is well understood. The application processor 56 may be in a device such as a mobile computing device (not shown) that includes a receptacle 60 configured to receive a SOUNDWIRE-XL cable such as the SOUNDWIRE-XL cable 58(1). The receptacle 60 may be operatively associated with an interface 62 (which may or may not be in the application processor 56) that includes appropriate electrical contacts to convey a differential data signal with an embedded clock signal to the two wires of the SOUNDWIRE-XL cable 58(1). The interface 62 may further be operatively coupled to a control system (labeled CS in the Figures) 64.

With continued reference to FIG. 1C, the bridge 52(1) is a master device relative to the bridges 52(2) and 52(3). Likewise, the bridges 52(2) and 52(3) are master devices for respective SOUNDWIRE systems 66(1) and 66(2). While not specifically illustrated, the bridges 52(1)-52(3) may include receptacles configured to receive the SOUNDWIRE-XL cables 58(1)-58(3) along with corresponding interfaces and/or control systems as needed. Exemplary situations where the expanded SOUNDWIRE system 50 may represent the connections include a multi-headset connection with or without shared audio or a split audio stream to multiple remote large displays. It should be appreciated that any of the SOUNDWIRE-XL cables 58(1)-58(3) may be unplugged at any given time and replaced with other SOUNDWIRE-XL elements which may not have the same data rate requirements as earlier elements.

Similarly, FIG. 1D is a block diagram of another exemplary expanded SOUNDWIRE system 70 with a bridge 72 and multiple SOUNDWIRE-XL segments 74(1) and 74(2) associated with an application processor 76 through SOUNDWIRE-XL cables 78(1) and 78(2). The application processor 76 is a master device relative to the bridge 72 and slave device 80. The application processor 76 may be in a device such as a mobile computing device (not shown) that includes receptacles 82(1) and 82(2) configured to receive a SOUNDWIRE-XL cable such as the SOUNDWIRE-XL cables 78(1) and 78(2). The receptacles 82(1) and 82(2) may be operatively associated with respective interfaces 84(1) and 84(2) (which may or may not be in the application processor 76) that include appropriate electrical contacts to convey a differential data signal with an embedded clock signal to the two wires of the SOUNDWIRE-XL cables 78(1) and 78(2). The interfaces 84(1) and 84(2) may further be operatively coupled to a control system (labeled CS in the Figures) 86.

With continued reference to FIG. 1D, as with the expanded SOUNDWIRE system 20 of FIG. 1B, the bridge 72 is a slave device with respect to the application processor 76, but a master device with respect to SOUNDWIRE system 88. Again, the bridge 72 may include receptacles and interfaces to allow operative interconnection with the SOUNDWIRE-XL cable 78(1).

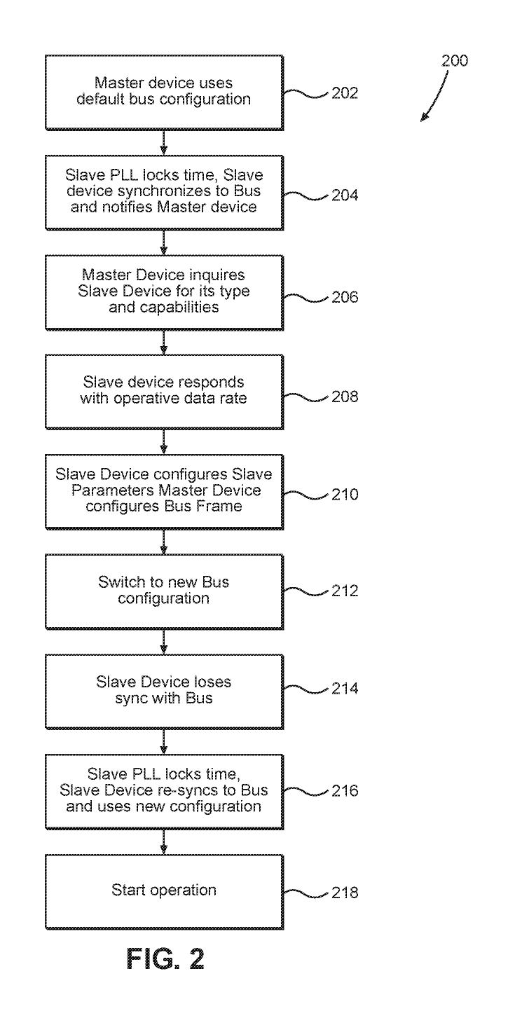

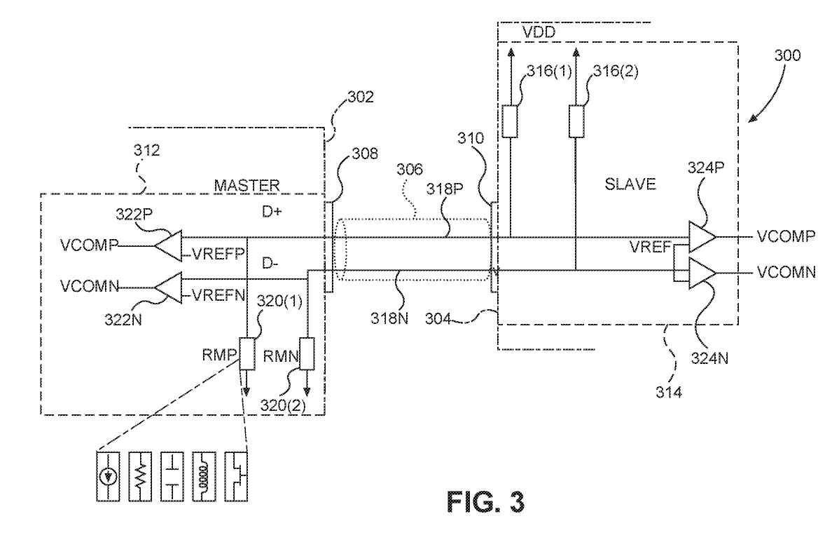

As alluded to above, SOUNDWIRE-XL cables may be plugged into a device or removed by the user. The presence or absence of differing slave devices and corresponding changes in the data rates require that the application processor have some way to determine what rate is appropriate. Exemplary aspects of the present disclosure provide, with reference to FIG. 2, a software technique through which the rate may be determined and, with reference to FIGS. 3-6, a hardware technique through which the rate may be determined

In this regard, FIG. 2 is a flowchart of an exemplary software solution to determining rate information for remote devices in an expanded SOUNDWIRE system such as the expanded SOUNDWIRE system 20, 50, or 70 of FIGS. 1B-1D. Process 200 of the software solution begins with the master device (e.g., the application processor 26, 56 or 76 or the bridges 22, 52(1)-52(3), or 72) using a default bus configuration (block 202). A SOUNDWIRE-XL cable associated with a slave device has been inserted into the receptacle associated with the master device. A phase locked loop (PLL) (not shown) in the slave device locks time, and the slave device synchronizes to the bus and notifies the master device (block 204). The master device inquires with the slave device for its type and capabilities (block 206). The slave device responds with its operative data rate (block 208). The process 200 continues with the slave device configuring slave parameters and the master device configuring bus frame (block 210). The master device then switches to a new bus configuration (block 212) including using the new data rate provided by the slave device. The slave device loses synchronization with the bus (block 214) based on the new bus configuration. The slave PLL then has to lock to the new bus clock, and the slave device resynchronizes to the new bus configuration (block 216). The slave device may then start operation (block 218).

While adequate to exchange the rate information, the process of synchronization on the default configuration and then having to resynchronize to the new configuration is slow. Further, this process does not readily detect removal of a cable. The hardware solution, described below with reference to FIGS. 3-6 provides a faster rate detection process and allows for removal detection. The hardware solution encodes the rate information by using elements at the slave and/or elements at the master to encode data rate information. In an exemplary aspect, these elements are resistors on the differential data line. Alternatively, the elements may be capacitors, inductors or metal oxide semiconductor (MOS) transistors. A voltage signal is applied to the differential data line to detect voltages, and, based on the detected voltage, the master device may learn the rate for the slave device.

In this regard, FIG. 3 is a simplified circuit diagram of a hardware solution to determining rate information for remote devices in an expanded SOUNDWIRE system 300. In particular, the expanded SOUNDWIRE system 300 includes a master device 302 and a slave device 304 coupled by a SOUNDWIRE-XL cable 306. The SOUNDWIRE-XL cable 306 plugs into receptacle 308 on the master device 302 and receptacle 310 on the slave device 304. In the master device 302, the receptacle 308 is associated with an interface 312. Similarly, in the slave device 304, the receptacle 310 is associated with an interface 314.

With continued reference to FIG. 3, the interface 314 includes elements 316(1) and 316(2) communicatively coupled to differential data lines 318P and 318N. Similarly, the interface 312 includes elements 320(1) and 320(2) communicatively coupled to the differential data lines 318P and 318N. In an exemplary aspect, the elements 316(1), 316(2), 320(1), and 320(2) are resistors and may be pull-up resistors (in the slave device 304) or pull-down resistors (in the master device 302). Alternatively, as illustrated in the expanded view of the element 320(1), the elements 316(1), 316(2), 320(1), and 320(2) may be capacitors, inductors, MOS transistors, or a current source. Note that current engineering realities require that using capacitors might require a very large capacitor to overcome any capacitance inherent in the SOUNDWIRE-XL cable 306. Such large capacitors may require a large amount of current from the master. Similar issues exist with respect to using inductors (although then it is the inherent inductance of the SOUNDWIRE-XL cable 306 which must be overcome). While not currently practical, the present disclosure does not exclude such solutions. In an exemplary aspect, the values of the elements 320(1) and 320(2) are fixed for all master devices, the values of the elements 316(1) and 316(2) are used to encode data rate information related to the slave device 304, and thus, the values may vary from slave device to slave device based on the encoded rate information. Comparators 322N and 322P may be used to compare voltage levels on the differential data lines 318N and 318P to reference voltages VREFN and VREFP, respectively. Similarly, comparators 324N and 324P may compare the voltage levels on the differential data lines 318N and 318P to a slave reference voltage VREF. The comparators 322N, 322P, 324N, and 324P can compare the voltage levels on the differential data lines 318N and 318P to multiple reference voltage levels with multiple comparators or use a single comparator switch to multiple reference voltages if needed or desired.

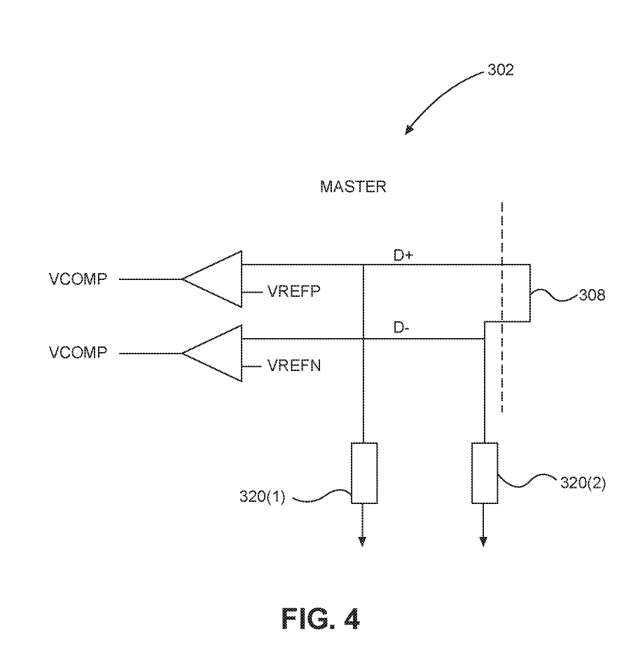

FIG. 4 is a simplified circuit diagram of the hardware solution of FIG. 3 when the remote devices are unplugged. In this regard, FIG. 4 illustrates the master device 302 with the receptacle 308 having no SOUNDWIRE-XL cable 306 plugged thereinto. The absence of the SOUNDWIRE-XL cable 306 creates an open circuit, and line state is only affected by the presence of the elements 320(1) and 320(2). When the line state changes in this manner, the master device 302 readily ascertains the disconnection of the SOUNDWIRE-XL cable 306 and the corresponding absence of any slave device.

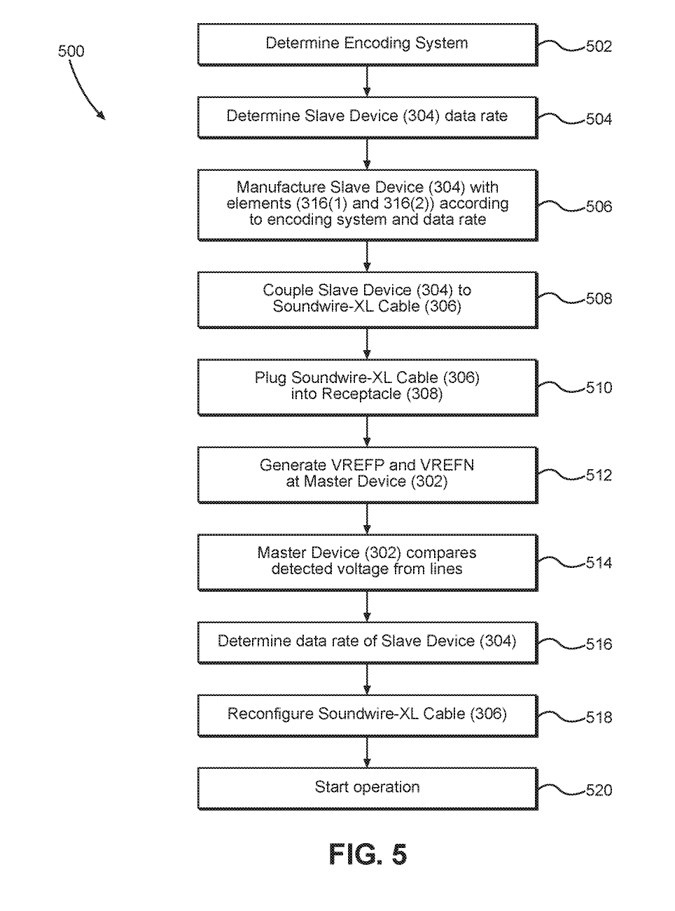

FIG. 5 is a flowchart of a process 500 associated with rate determination according to the hardware solution of FIG. 3. The process 500 begins by determining an encoding system for slave devices such as the slave device 304 (block 502). In particular, the encoding system is designed to convey information about a data rate used by slave devices. If the elements 316(1) and 316(2) are capable of taking two values each (e.g., two different resistance values (e.g., 20 kΩ and 10 kΩ for resistors)), then each slave device is capable of having eight states that may be associated with data rates (although with more values for the elements 316(1) and 316(2), this number may be expanded). For the sake of illustration, in the process 500, it is assumed that the elements 316(1) and 316(2) are pull-up resistors and the elements 320(1) and 320(2) are pull-down resistors. In an exemplary aspect, the values the pull-up resistors 316(1) and 316(2) can take are 20 kΩ, 10 kΩ or zero kΩ. The values of the pull-down resistors 320(1) and 320(2) are fixed at 10 Ω. Thus, each line has three states (i.e., 0, ½ Vdd>Y>⅓Vdd, and Y>½Vdd). In theory, there are actually a total of nine states, but 0,0 corresponds to disconnected. This is summarized in Table 1 below:

TABLE 1
POSSIBLE LINE STATES

| | | VCOMP | | | VCOMP |
|---|---|---|---|---|---|
| RMP | 10k | | RMP | 10k | |
| RSP | 20k | ⅓*VDD | RSP | 10k | ½*VDD |
| | | VCOMN | | | VCOMN |
| RMN | 10k | | RMN | 10k | |
| RSP | 20k | ⅓*VDD | RSP | 10k | ½*VDD |

With continued reference to FIG. 5, the process 500 continues by determining a data rate for the slave device 304 (block 504). The designer or manufacturer manufactures the slave device 304 with the elements 316(1) and 316(2) (e.g., pull-up resistors) according to the encoding system and data rate (block 506). The slave device 304 is coupled to the SOUNDWIRE-XL cable 306 (block 508). In an exemplary aspect, the SOUNDWIRE-XL cable 306 is integral with the slave device 304 and is coupled by the manufacturer. In an alternate exemplary aspect, the SOUNDWIRE-XL cable 306 is double-ended and the end user inserts the SOUNDWIRE-XL cable 306 into the receptacle 310 on the slave device 304. The end user then plugs the SOUNDWIRE-XL cable 306 into the receptacle 308 (block 510), which couples the slave device 304 to the master device 302. The master device 302 may use this plugging step to detect insertion, or the insertion may be detected in the next step. The master device 302 generates a positive and a negative reference voltage VREFP and VREFN (block 512) to produce a differential signal, which propagates down the SOUNDWIRE-XL cable 306 and is modified by the pull-up resistors 316(1) and 316(2). The master device 302 compares, using the comparators 322N and 322P, the detected voltage from the differential data lines 318N and 318P of the SOUNDWIRE-XL cable 306 to the encoding system (block 514). This comparison may be done using a look-up table. Based on the comparison, the master device 302 determines the data rate of the slave device 304 (block 516), (e.g., finding the corresponding entry in the look-up table). The master device 302 then reconfigures the data lines of the SOUNDWIRE-XL cable 306 (block 518) to operate at the determined data rate and starts operation (block 520). Note that the master device 302 may also generate VREFP and VREFN when the SOUNDWIRE-XL cable 306 is disconnected. The values on the differential data lines 318N and 318P are then 0,0, and the master device 302 concludes that the SOUNDWIRE-XL cable 306 is disconnected or that there is no SOUNDWIRE-XL cable 306 inserted into the receptacle 308.

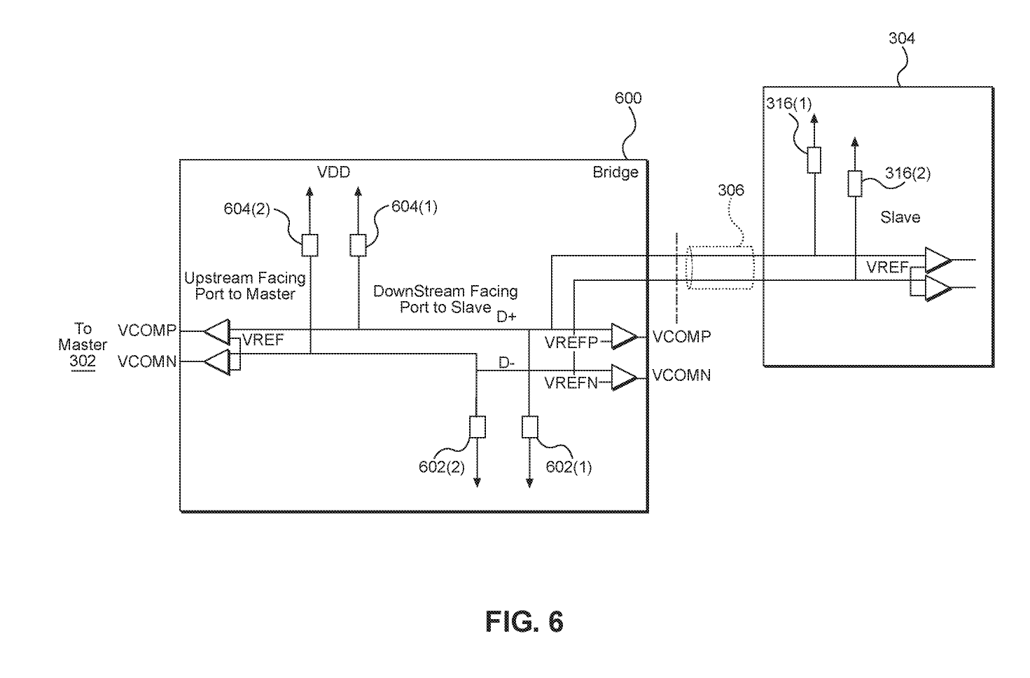

FIG. 6 is a simplified circuit diagram of a hardware solution for determining rate information for remote devices using a hub or bridge 600. The bridge 600 will reflect downstream resistor values of the slave device 304 to the upstream facing master device 302. The bridge 600 includes elements 602(1) and 602(2) on the downstream side and elements 604(1) and 604(2) on the upstream side. In an exemplary aspect, these are pull-down and pull-up resistors or other element as described above. Use of the bridge 600 may allow for multiple SOUNDWIRE-XL cables 306, which may in turn allow for distances greater than two meters to be implemented. Further, use of the bridge 600 may enable functions for different types of speakers, different types of microphones, and the like.

The systems and methods for rate detection for SOUNDWIRE-XL cables according to aspects disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a smart phone, a tablet, a phablet, a server, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, and an automobile.

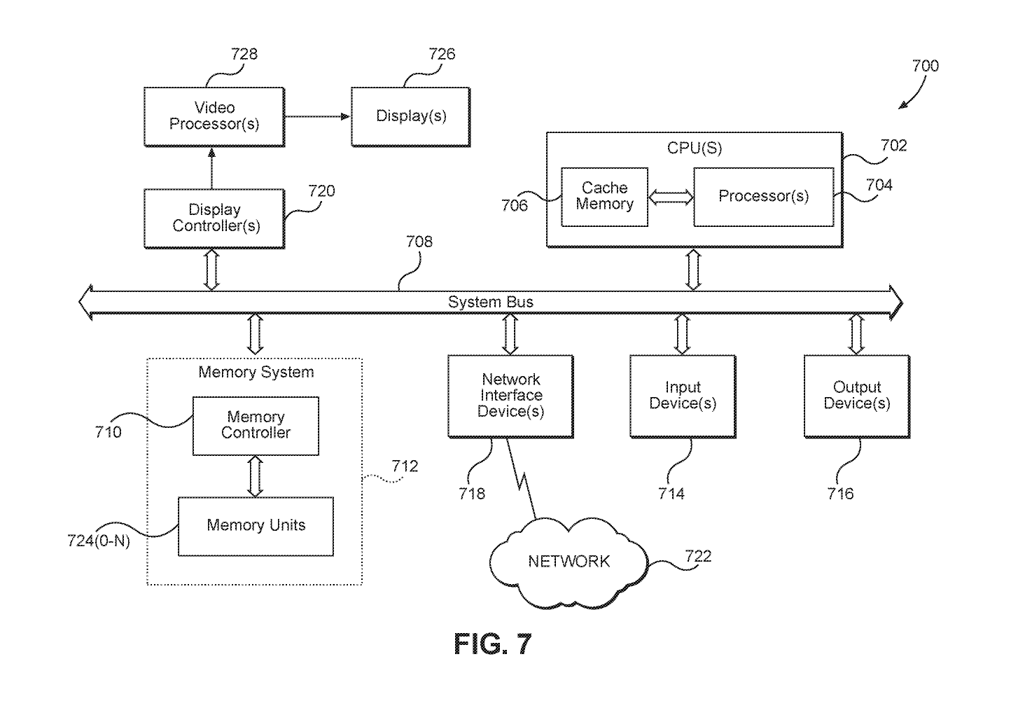

In this regard, FIG. 7 illustrates an example of a processor-based system 700 that can employ the systems and methods for rate detection for SOUNDWIRE cables illustrated in FIGS. 2-6. In this example, the processor-based system 700 includes one or more central processing units (CPUs) 702, each including one or more processors 704. The CPU(s) 702 may be the master device 302 of FIG. 3. The CPU(s) 702 may have cache memory 706 coupled to the processor(s) 704 for rapid access to temporarily stored data. The CPU(s) 702 is coupled to a system bus 708 and can intercouple master and slave devices included in the processor-based system 700. As is well known, the CPU(s) 702 communicates with these other devices by exchanging address, control, and data information over the system bus 708. For example, the CPU(s) 702 can communicate bus transaction requests to a memory controller 710 as an example of a slave device. Although not illustrated in FIG. 7, multiple system buses 708 could be provided, wherein each system bus 708 constitutes a different fabric.

Other master and slave devices can be connected to the system bus 708. As illustrated in FIG. 7, these devices can include a memory system 712, one or more input devices 714, one or more output devices 716, one or more network interface devices 718, and one or more display controllers 720, as examples. The input device(s) 714 can include any type of input device, including, but not limited to, input keys, switches, voice processors, etc. The output device(s) 716 can include any type of output device, including, but not limited to, audio, video, other visual indicators, etc. The network interface device(s) 718 can be any devices configured to allow exchange of data to and from a network 722. The network 722 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 718 can be configured to support any type of communications protocol desired. The memory system 712 can include one or more memory units 724(0-N).

The CPU(s) 702 may also be configured to access the display controller(s) 720 over the system bus 708 to control information sent to one or more displays 726. The display controller(s) 720 sends information to the display(s) 726 to be displayed via one or more video processors 728, which process the information to be displayed into a format suitable for the display(s) 726. The display(s) 726 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master devices, and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A master device comprising:
a receptacle configured to receive a SOUNDWIRE extension (SOUNDWIRE-XL) cable;
an interface comprising a differential data line with an embedded clock signal, the interface coupled to the receptacle; and
a control system configured to:
generate voltage levels on the differential data line;
detect the voltage levels on the differential data line as modified by a remote slave device; and
determine a data rate for the remote slave device based on the detected voltage levels.

2. The master device of claim 1, wherein the interface comprises at least one master element configured to adjust the voltage levels generated on the differential data line.

3. The master device of claim 2, wherein the at least one master element comprises a pull-down resistor.

4. The master device of claim 3, wherein the pull-down resistor comprises a 10 kΩ resistor.

5. The master device of claim 1, wherein the control system is configured to reconfigure the differential data line based on the data rate determined by the control system.

6. The master device of claim 1, wherein the control system is configured to use a look-up table to determine the data rate.

7. The master device of claim 2, wherein the at least one master element is selected from the group consisting of: inductor, capacitor, and metal oxide semiconductor (MOS) transistor.

8. The master device of claim 1 integrated into a device selected from the group consisting of: a set top box; an entertainment unit; a navigation device; a communications device; a fixed location data unit; a mobile location data unit; a mobile phone; a cellular phone; a smart phone; a tablet; a phablet; a server; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; and an automobile.

9. A method of controlling a SOUNDWIRE extension (SOUNDWIRE-SL) cable, comprising:
at a master device, generating voltage levels on a differential data line;
detecting the voltage levels on the differential data line as modified by a remote slave device; and
determining a data rate for the remote slave device based on the detected voltage levels.

10. The method of claim 9, further comprising detecting insertion of the SOUNDWIRE-XL cable at a receptacle in the master device.

11. The method of claim 9, further comprising reconfiguring the differential data line for the data rate based on the determining.

12. The method of claim 9, further comprising using a master element at the master device to generate the voltage levels on the differential data line.

13. The method of claim 12, wherein using the master element comprises using an element selected from the group consisting of: a pull-down resistor, a capacitor, an inductor, and a metal oxide semiconductor (MOS) transistor.

14. The method of claim 12, wherein determining the data rate comprises using a look-up table to determine the data rate.

15. A slave device comprising:
a receptacle configured to receive a SOUNDWIRE extension (SOUNDWIRE-XL) cable;
an interface comprising a differential data line having an embedded clock signal thereon, the interface comprising at least one slave element configured to provide encoded data rate information about the slave device.

16. The slave device of claim 15, wherein the at least one slave element comprises a pull-up resistor.

17. The slave device of claim 15, wherein the at least one slave element comprises an element selected from the group consisting of: a capacitor, an inductor, and a metal oxide semiconductor (MOS) transistor.

18. The slave device of claim 15, wherein the slave device comprises a phase locked loop (PLL) configured to use the embedded clock signal.

19. A method of detecting rate information for a remote slave device comprising:
detecting voltage levels on a differential data line based on one or more pull-up resistors at a remote slave device;
decoding the voltage levels to determine a data rate.
